(19) United States
(12) Patent Application Publication
(10) Pub. No.: US 2024/0130077 A1
(43) Pub. Date: Apr. 18, 2024

(54) MULTICHANNEL MANIFOLD COLD PLATE

(71) Applicant: 3M INNOVATIVE PROPERTIES COMPANY, St. Paul, MN (US)

(72) Inventors: Qihong Nie, Woodbury, MN (US); Steven D. Solomonson, Shoreview, MN (US); Vadim N. Savvateev, St. Paul, MN (US); Nicholas A. Proite, St. Paul, MN (US); Myron K. Jordan, Apple Valley, MN (US); Glendon D. Kappel, Eagan, MN (US); Elizaveta Y. Plotnikov, Woodbury, MN (US); Dylan T. Cosgrove, Oakdale, MN (US); Andrew K. Penning, Forest Lake, MN (US); Sung Moon, Woodbury, MN (US)

(21) Appl. No.: 18/547,194

(22) PCT Filed: Feb. 18, 2022
(86) PCT No.: PCT/IB2022/051480

§ 371 Date: Aug. 21, 2023

Related U.S. Application Data
(60) Provisional application No. 63/162,196, filed on Mar. 17, 2021.

(51) Int. Cl. H05K 7/20

(52) U.S. Cl. CPC H05K 7/20254; H05K 7/20272

(57) ABSTRACT

A multichannel manifold cold plate with microchannels for cooling electronics. A main inlet is on a side of the microchannels opposite the cold plate and includes inlet channels with nozzles adjacent the microchannels. A main outlet is on a side of the microchannels opposite the cold plate and includes outlet channels with nozzles adjacent the microchannels. The inlet channels are interleaved with the outlet channels. In operation, the main inlet delivers a cooling fluid to the cold plate microchannels via the inlet channels and nozzles, and the main outlet receives the cooling fluid from the microchannels via the outlet channels and nozzles. This configuration provides a cooling fluid distribution pattern for efficient cooling of the electronics.

### BACKGROUND

Currently, most chip components of electronics are cooled by forced air convection, but this cooling will not be sufficient for next generation, higher powered electronics which require efficient and compact cooling solutions to maintain acceptable operating temperatures. Liquid cooling of those electronic components, such as a central processing unit (CPU), by microchannel cold plates, also known as direct to chip cooling, has been increasingly adapted as an efficient cooling solution for the thermal management of servers in data centers. Efficient cooling performance can be achieved for the microchannel based cold plate by reducing the channel size. However, a reduction in channel size can result in a high pressure drop, which is a disadvantage for the microchannel based cooling solutions.

### SUMMARY

A first multichannel manifold cold plate includes a cold plate and microchannels on the cold plate. A plurality of inlets on the microchannels deliver a cooling fluid to the microchannels, and a plurality of outlets on the microchannels receive the cooling fluid from the microchannels. The inlets are interleaved with the outlets.

A second multichannel manifold cold plate includes a cold plate and microchannels on the cold plate. A main inlet is on a side of the microchannels opposite the cold plate and includes inlet channels in fluid communication with the main inlet with nozzles on the inlet channels adjacent the microchannels. A main outlet is on a side of the microchannels opposite the cold plate and includes outlet channels in fluid communication with the main inlet with nozzles on the outlet channels adjacent the microchannels.

The inlet channels are interleaved with the outlet channels. The main inlet delivers a cooling fluid to the cold plate microchannels via the manifold inlet channels and nozzles, and the main outlet receives the cooling fluid from the microchannels via the outlet channels and nozzles.

### BRIEF DESCRIPTION OF THE DRAWINGS

FIG. 1 is a side view illustrating a manifold cold plate.

FIG. 2 is a perspective view illustrating a multichannel manifold flow pattern that has three inlets and four outlets.

FIG. 3 is a cross-sectional view showing a coolant distribution within the multichannel manifold cold plate of FIG. 2.

FIG. 4A is a side view of inlets and outlets located at the top of manifold channels.

FIG. 4B is a perspective view illustrating the inlet path for the manifold channels of FIG. 4A.

FIG. 4C is a perspective view illustrating the outlet path for the manifold channels of FIG. 4A.

FIG. 5 is a side view illustrating a multichannel flow manifold with three inlets and two outlets.

FIG. 6A is a perspective view illustrating the configuration and components for the inlet in the multichannel manifold of FIG. 5.

FIG. 6B is a perspective view illustrating the configuration and components for the outlet in the multichannel manifold of FIG. 5.

FIG. 7A is a perspective view of a two-segment microchannel cold plate.

FIG. 7B is a perspective view of a four-segment microchannel cold plate.

### DETAILED DESCRIPTION

Embodiments include manifold designs for high power density electronics thermal management. The designs achieve low thermal resistance as well as a low pressure drop. The manifolds can be attached to or integrated with microchannel cooling devices. The manifold designs can include a multichannel manifold having multiple inlets and outlets for delivering a cooling fluid to the microchannels or having a single main inlet and outlet with multiple distribution channels for delivering the cooling fluid. Alternatively, the designs can be used without microchannels. The ratio of the inlets to the outlets and the number of distribution channels can be configured to deliver high cooling performance while maintaining relatively low pressure drop. Varying distribution channel sizes also helps to deliver uniform flow across the microchannels.

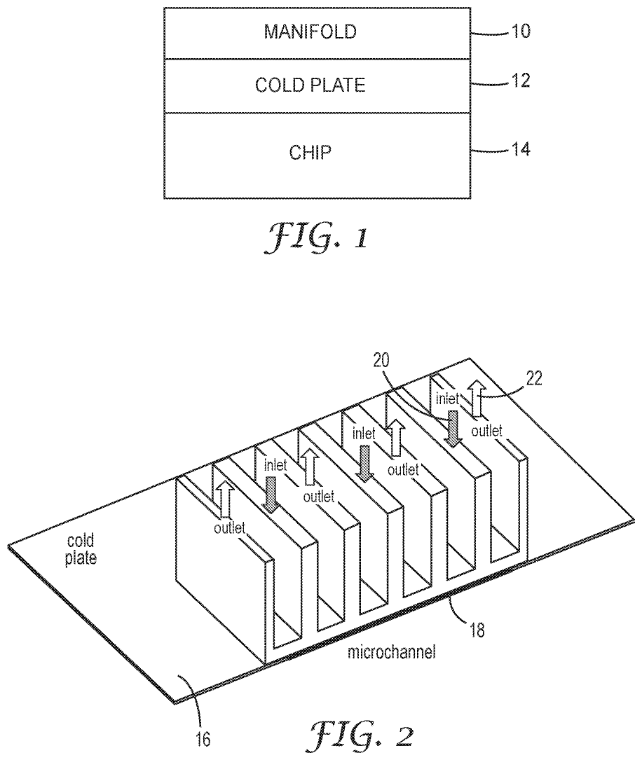

FIG. 1 is a side view illustrating a multichannel manifold 10 for providing a cooling fluid or coolant to a cold plate 12 having microchannels for use in cooling an integrated circuit chip 14 or other electronic components. A thermal interface material can be located between cold plate 12 and chip 14. These electronic components can be located within a data center, for example, or other locations.

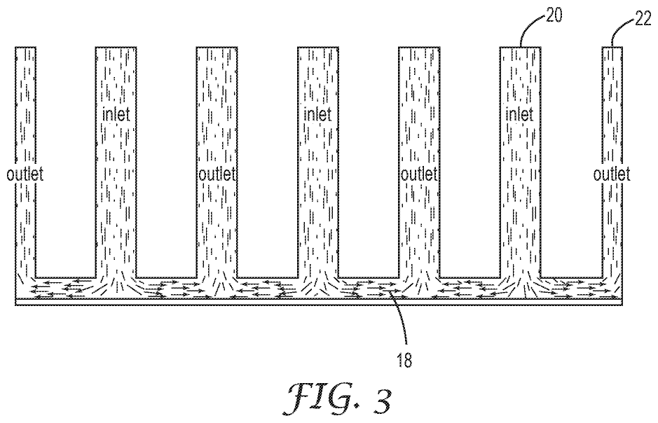

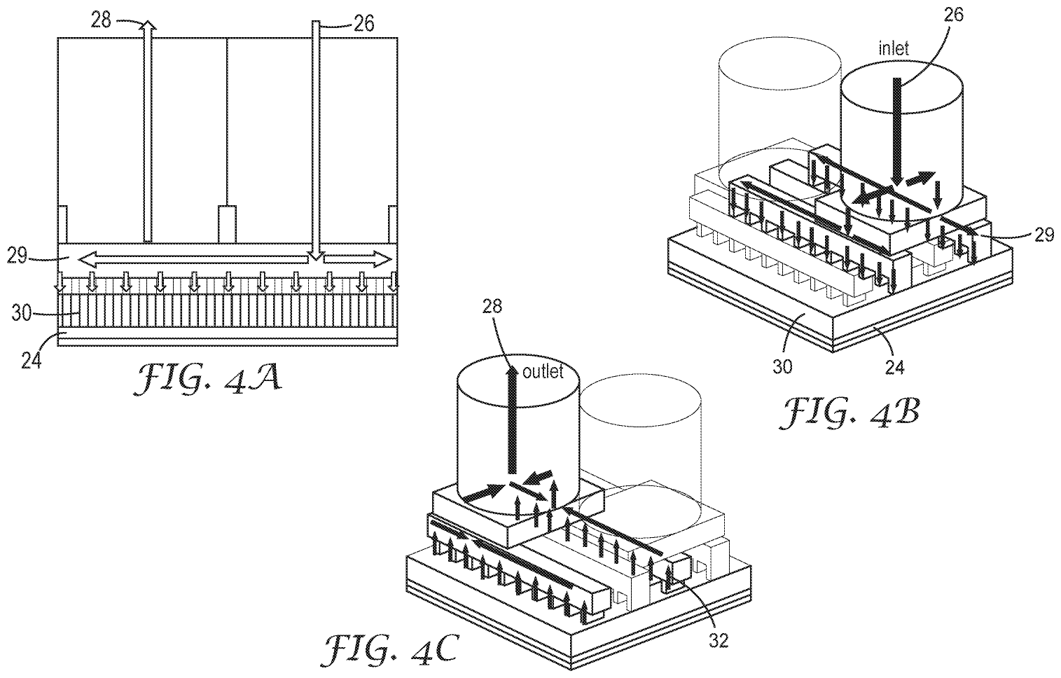

FIG. 2 is a perspective view illustrating a multichannel manifold configuration pattern that has three inlets 20 and four outlets 22 on a cold plate 16 having microchannels 18. FIG. 3 is a cross-sectional view showing a coolant distribution within the multichannel manifold cold plate between inlets 20 and outlets 22. As shown, inlets 20 and outlets 22 are located on microchannels 18, for example at a 90° angle to microchannels 18 or substantially perpendicular to microchannels 18 to achieve a desired flow length and distribution of the coolant.

Also, inlets 20 are interleaved with outlets 22, meaning that the inlets alternate with the outlets. The inlets and outlets can be interleaved on a one-to-one basis such that one inlet alternates with one outlet or interleaved on other bases, for example two inlets alternating with one outlet or one inlet alternating with two outlets. The type of interleaving of inlets and outlets can be determined, for example, based upon a desired coolant flow and distribution among the microchannels. This configuration of inlets and outlets provides for an effective reduction of coolant flow length from inlet to outlet and direct introduction of coolant flow at the location of inlet.

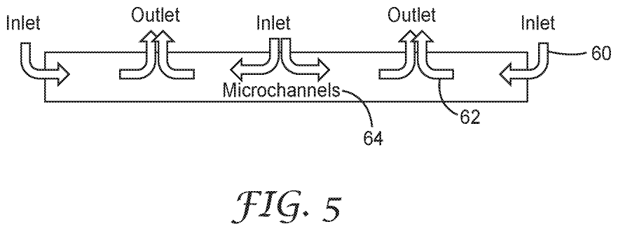

FIG. 4A is a side view of inlets and outlets located at the top of manifold channels. FIGS. 4B and 4C are perspective views illustrating, respectively, the inlet path and outlet path for the manifold channels of FIG. 4A. As shown in FIG. 4A, this manifold has a main inlet 26 for providing a cooling fluid to an inlet channel 29 and, in turn, to microchannels 30 on a cold plate 24. FIG. 4B illustrates the main inlet 26 providing the cooling fluid to two inlet channels 29 for delivery of the cooling fluid via inlet nozzles to microchannels 30. FIG. 4C illustrates two outlet channels 32 for receiving the cooling fluid from microchannels 30 and delivering the cooling fluid to a main outlet 28.

The configuration of FIGS. 4A-4C has the same number of inlet channels and outlet channels for providing distribution channels between the main inlet to the manifold channels and to the main outlet. The coolant flow and distribution pattern are shown by the arrows in FIGS. 4A-4C. As shown, main inlet 26 and main outlet 28 are located at, for example, a 90° angle to microchannels 30 or substantially perpendicular to microchannels 30 to achieve a desired flow length and distribution of the coolant.

Inlet channels 29 are interleaved with outlet channels 32, meaning that the inlet channels alternate with the outlet channels. The interleaving can be on, for example, a one-to-one basis or other bases as described for FIGS. 2 and 3. The inlet and outlet distribution channels help to distribute the coolant to the manifold microchannels efficiently. Furthermore, those distribution channels with nozzles will introduce the impingement of coolant onto the microchannels, enhancing the heat transfer efficiency.

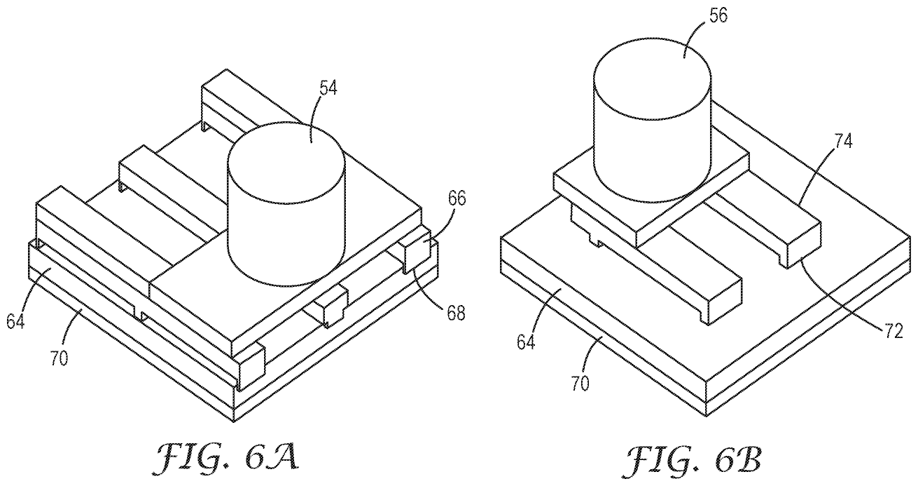

FIG. 5 is a side view illustrating a multichannel flow manifold with three inlet channels 60 and two outlet channels 62 for providing a cooling fluid to microchannels 64. In the configuration shown in FIG. 5, one inlet channel is at the center of the manifold and the other two inlet channels are at the two ends or sides of the manifold. The outlet channels are between the center and end inlet channels.

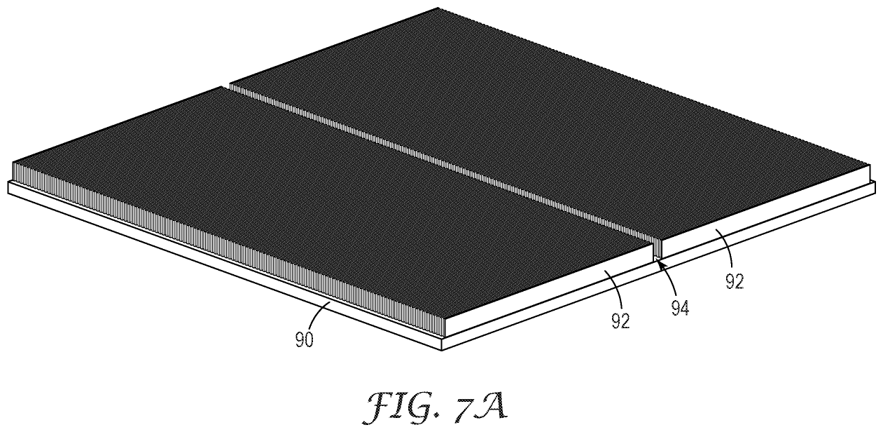

FIGS. 6A and 6B are perspective views illustrating the configuration and components for, respectively, the inlet and outlet in the multichannel manifold of FIG. 5. As shown in FIG. 6A, a main inlet 54 provides a cooling fluid to three inlet channels 66 each having inlet nozzles 68 delivering the cooling fluid to microchannels 64 on a cold plate 70. As shown in FIG. 6B, a main outlet 56 receives a cooling fluid from two outlet channels 74 each having outlet nozzles 72 receiving the cooling fluid from microchannels 64 on a cold plate 70.

As shown, main inlet 54 and main outlet 56 are located at, for example, a 90° angle to microchannels 64 or substantially perpendicular to microchannels 64 to achieve a desired flow length and distribution of the coolant. Inlet channels 66 are interleaved with outlet channels 74, meaning that the inlet channels alternate with the outlet channels. The interleaving can be on, for example, a one-to-one basis or other bases as described for FIGS. 2 and 3.

The following configurations for the multichannel manifolds of FIGS. 6A-6B yields advantages of both low pressure drop and low thermal resistance. The inlet and outlet channels can include spray nozzles or snouts, as shown. The center inlet channel size can be 1 mm wide, and the end inlet channels width can be 250 microns or 500 microns to provide the multichannel manifold with a lower pressure drop and thermal resistance value than the center flow while maintaining similar or more uniform temperature gradient for the heat source. Both configurations for the inlet channel widths, 250 microns for the center inlet channel and 500 microns for the end inlets channels, can provide for a low pressure drop.

The manifold distribution inlet and outlet channels can have different sizes. The center inlet channel can be smaller, having a width less than the width of the outer inlet channels, for better flow distribution uniformity. The spray nozzles or snouts of the center inlet channel can also have a varying size for better fluid distribution uniformity. The outlet channels can be configured in a similar or different manner than the inlet channels depending upon, for example, a desired coolant flow and distribution pattern.

Table 1 provides parameters for two exemplary designs based upon the configuration shown in FIGS. 6A-6B.

TABLE 1

| Parameter | Design 1 | | Design 2 | |
|---|---|---|---|---|
| center inlet width | 1 | mm | 1 | mm |
| outer inlet width | 250 | microns | 500 | microns |
| outlet width | 1 | mm | 1 | mm |
| distance between center inlet and outlets | 6750 | microns | 6500 | microns |
| distance between outer inlets and outlets | 5625 | microns | 5750 | microns |
| distance between outer inlets | 25 | mm | 25 | mm |

The following are exemplary materials and configurations for the manifolds described herein.

The inlets, outlets, main inlet, main outlet, channels, and nozzles can be composed of, for example, a variety of materials having low-thermal conductance such as injection molded plastic, composite materials, or low thermal conductive metals. For example, those components can be composed of copper for high thermal conductivity. The copper can be treated to reduce risk of oxidation (e.g., nickel plating, passivation, etc.). Other possible materials are aluminum, silvers, and eutectic alloy of silver and copper.

The cold plate can be composed of, for example, copper or other metals having a high thermal conductivity.

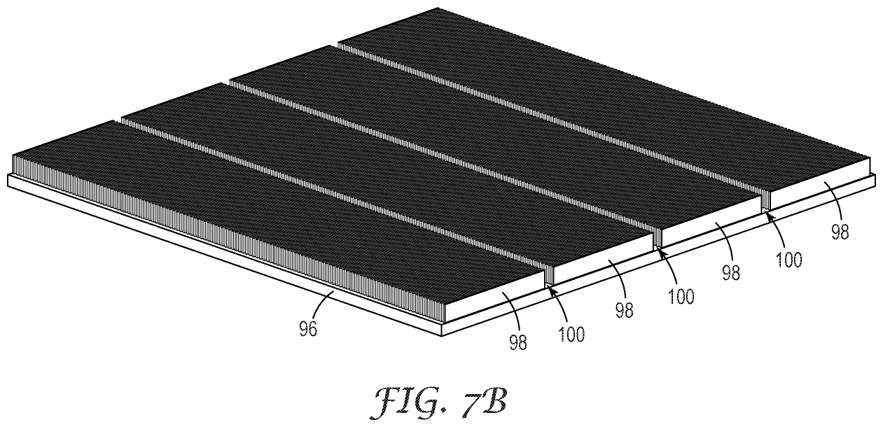

The cold plate microchannels can be formed integrally with the cold plate through machining or can be formed on the cold plate through additive manufacturing (3D printing) or electroplating. Alternatively, the cold plate microchannels can be in a separate component on the cold plate. The cold plate microchannels can comprise fins, for example the fins as shown for microchannels 30 in FIG. 4A. The fins are typically continuous and parallel with one another across a section of the cold plate for cooling. Alternatively, the fins can be discontinuous, non-parallel with one another, or curved or wavy in a cross-sectional view. The fins or other microchannel structures can be segmented as shown in FIGS. 7A and 7B. FIG. 7A is a perspective view of a cold plate 90 having two segmented microchannels 92 forming a channel 94. FIG. 7B is a perspective view of a cold plate 96 having four segmented microchannels 98 forming channels 100. The cold plate microchannels can have, for example, approximately a 200 micron pitch with 100 micron wide channels up to a 600 micron pitch with 300 micron wide channels. The width for the microchannels can be, for example, from 50 microns to 1000 microns with a height from 100 microns to 5 mm.

1. A multichannel manifold cold plate, comprising:
a cold plate;
microchannels on the cold plate;
a plurality of inlets on the cold plate microchannels for delivering a cooling fluid to the cold plate microchannels; and
a plurality of outlets on the cold plate microchannels for receiving the cooling fluid from the cold plate microchannels,
wherein the inlets are interleaved with the outlets.

2. The multichannel manifold of claim 1, wherein a number of the outlets is greater than a number of the inlets.

3. The multichannel manifold of claim 1, wherein the inlets are interleaved with the outlets on a one-to-one basis.

4. The multichannel manifold of claim 1, wherein the inlets are substantially perpendicular to the cold plate microchannels.

5. The multichannel manifold of claim 1, wherein the outlets are substantially perpendicular to the cold plate microchannels.

6. The multichannel manifold of claim 1, wherein the cold plate microchannels comprise fins.

7. The multichannel manifold of claim 1, wherein the cold plate microchannels are segmented.

8. The multichannel manifold of claim 7, wherein the segmented cold plate microchannels form a channel.

9. A multichannel manifold cold plate, comprising:
a cold plate;
microchannels on the cold plate;
a main inlet on a side of the cold plate microchannels opposite the cold plate;
a plurality of inlet channels in fluid communication with the main inlet;
a plurality of inlet nozzles on the inlet channels adjacent the cold plate microchannels;
a main outlet on a side of the cold plate microchannels opposite the cold plate;
a plurality of outlet channels in fluid communication with the main outlet; and
a plurality of outlet nozzles on the outlet channels adjacent the cold plate microchannels,
wherein the inlet channels are interleaved with the outlet channels, the main inlet delivers a cooling fluid to the cold plate microchannels via the inlet channels and the inlet nozzles, and the main outlet receives the cooling fluid from the cold plate microchannels via the outlet channels and the outlet nozzles.

10. The multichannel manifold of claim 9, wherein a number of the inlet channels is equal to a number of the outlet channels.

11. The multichannel manifold of claim 9, wherein a number of the inlet channels is greater than a number of the outlet channels.

12. The multichannel manifold of claim 9, wherein the inlets channels are interleaved with the outlet channels on a one-to-one basis.

13. The multichannel manifold of claim 9, wherein the main inlet is substantially perpendicular to the cold plate microchannels.

14. The multichannel manifold of claim 9, wherein the main outlet is substantially perpendicular to the cold plate microchannels.

15. The multichannel manifold of claim 9, wherein the plurality of inlet nozzles are spaced apart from the cold plate microchannels.

16. The multichannel manifold of claim 9, wherein the plurality of outlet nozzles are spaced apart from the cold plate microchannels.

17. The multichannel manifold of claim 9, wherein the cold plate microchannels comprise fins.

18. The multichannel manifold of claim 9, wherein the cold plate microchannels are segmented.

19. The multichannel manifold of claim 18, wherein the segmented cold plate microchannels form a channel.
